(19) United States
(12) Patent Application Publication
(10) Pub. No.: US 2026/0215233 A1
(43) Pub. Date: Jul. 23, 2026

(54) METHODS OF FORMING A SEMICONDUCTOR DEVICE

(71) Applicant: DuPont Electronic Materials International, LLC, Marlborough, MA (US)

(72) Inventors: Soojung Clara LEEM, Hwaseong-si (KR); Min Kyung JANG, Hwaseong-si (KR); HyeonWoo SHIN, Hwaseong-si (KR); Youngeun BAE, Hwaseong-si (KR); Jae Hwan SIM, Hwaseong-si (KR)

(21) Appl. No.: 18/933,213

(22) Filed: Oct. 31, 2024

Related U.S. Application Data
(60) Provisional application No. 63/616,683, filed on Dec. 31, 2023.

(51) Int. Cl. H10P 76/20; C08F 12/08; C08F 12/20; C08F 12/24; C08F 20/14; C08F 20/18; C08F 20/22; C08F 20/28; C08F 20/30; C08F 20/32; C08G 8/10; G03F 7/038; G03F 7/039; G03F 7/16; H10P 50/00; H10P 50/66

(52) U.S. Cl. CPC H10P 76/204; C08F 12/08; C08F 12/20; C08F 12/24; C08F 20/14; C08F 20/18; C08F 20/22; C08F 20/28; C08F 20/30; C08F 20/32; C08G 8/10; G03F 7/0388; G03F 7/039; G03F 7/168; H10P 50/667; H10P 50/71

(57) ABSTRACT

A method of forming a semiconductor device, comprising: (a) providing a semiconductor substrate comprising a metal layer; (b) forming an organic underlayer on the metal layer from an organic underlayer coating composition comprising a crosslinkable compound and a solvent, wherein the organic underlayer is self-crosslinkable and is substantially free of acid generators; (c) curing the organic underlayer, thereby crosslinking the organic underlayer; (d) patterning the cured organic underlayer, thereby exposing regions of the metal layer that are not covered by the patterned organic underlayer; (e) applying an overcoat coating composition on the substrate comprising the patterned organic underlayer, wherein the overcoat coating composition comprises a crosslinkable compound that is crosslinkable with the patterned organic underlayer; and an organic solvent; wherein the overcoat coating composition is substantially free of acid generators; (f) curing the overcoat coating composition to cause crosslinking between the compound and the patterned organic underlayer, wherein the resulting overcoat comprises a first portion that is crosslinked with the organic underlayer and a second portion that is not crosslinked with the organic underlayer; (g) removing the second portion of the overcoat from the substrate with an organic-based solution; and (h) wet etching the metal layer using the patterned organic underlayer and the first portion of the overcoat as an etching mask. The methods find particular use in the formation of fine lithographic patterns in the semiconductor manufacturing industry.

### BACKGROUND OF THE INVENTION

### 1. Field of the Invention

The invention relates generally to the manufacture of electronic devices. More specifically, this invention relates to methods of forming a semiconductor device that involve patterning metal layers by wet etching. The methods find particular use in the formation of fine lithographic patterns in the semiconductor manufacturing industry.

### 2. Description of the Related Art

Photoresists are photosensitive films used for the transfer of images to a substrate. A coating layer of a photoresist is formed on a substrate and the photoresist layer is then exposed by a source of activating radiation, directly or more typically through a patterned photomask. Following exposure, the photoresist is developed to provide a relief image that permits selective processing of a substrate.

Reflection of activating radiation used to expose a photoresist often poses limits on resolution of the image patterned in the photoresist layer. Reflection of radiation from the substrate/photoresist interface can produce spatial variations in the radiation intensity in the photoresist, resulting in non-uniform photoresist linewidth upon development. Radiation also can scatter from the substrate/photoresist interface into regions of the photoresist where exposure is non-intended, again resulting in linewidth variations. Such reflection and light scattering can be particularly problematic where the layer to be patterned on the substrate is reflective, as is typical when patterning a metal layer.

A known approach to reduce the problem of reflected radiation during photoresist layer exposure has been the use of a radiation absorbing organic underlayer interposed between the substrate surface and the photoresist coating layer (see, e.g., US 2016/0187778 A1). To increase the integration density of semiconductor devices and allow for the formation of structures having extremely fine dimensions, for example, in the nanometer range, process materials and processing tools having high-resolution capabilities have been and continue to be developed. With such fine geometries and accompanying increases in the complexity and delicacy of the devices, as well as increasingly harsher wet-etching conditions being used in the industry, there is a need for organic photoresist underlayers having improved wet-etch resistance.

In patterning metal layers on the substrate, increased wet-etch resistance of organic underlayers has conventionally been achieved by strengthening the interaction between the photoresist underlayer and underlying metal layer such as by incorporation of metal-interacting moieties into the underlayer. One such technique is disclosed in U.S. Pat. No. 10,527,942 B2, which describes an organic underlayer comprising (i) one or more glycidyl groups, and (ii) one or more aromatic groups that each comprises two or more substituents that comprise hydroxy, thiol and/or amine moieties. The incorporation of metal-interacting moieties, however, may adversely impact certain desired underlayer properties such as gap-filling and planarizing properties. A method for increasing the resistance of an organic underlayer to wet etching chemicals without materially altering other desired properties of the underlayer would therefore be desired.

There is a need in the art for improved methods of forming semiconductor devices that address one or more problems associated with the state of the art.

### SUMMARY OF THE INVENTION

Provided are new methods of forming a semiconductor device which involve use of a photoresist underlayer and overcoat layer which provides enhanced wet-etch resistance when patterning an underlying metal layer. The methods comprise: (a) providing a semiconductor substrate comprising a metal layer; (b) forming an organic underlayer on the metal layer from an organic underlayer coating composition comprising a crosslinkable compound and a solvent, wherein the organic underlayer is self-crosslinkable and is substantially free of acid generators; (c) curing the organic underlayer, thereby crosslinking the organic underlayer; (d) patterning the cured organic underlayer, thereby exposing regions of the metal layer that are not covered by the patterned organic underlayer; (e) applying an overcoat coating composition on the substrate comprising the patterned organic underlayer, wherein the overcoat coating composition comprises a crosslinkable compound that is crosslinkable with the patterned organic underlayer; and an organic solvent; wherein the overcoat coating composition is substantially free of acid generators; (f) curing the overcoat coating composition to cause crosslinking between the compound and the patterned organic underlayer, wherein the resulting overcoat comprises a first portion that is crosslinked with the organic underlayer and a second portion that is not crosslinked with the organic underlayer; (g) removing the second portion of the overcoat from the substrate with an organic-based solution; and (h) wet etching the metal layer using the patterned organic underlayer and the first portion of the overcoat as an etching mask.

In a further aspect, the methods further comprise: (i) removing the patterned organic underlayer and the crosslinked portion of the overcoat composition from the substrate. In certain preferred aspects, the metal layer can be chosen from tungsten, titanium nitride, titanium dioxide, titanium silicon nitride, or tungsten carbonitride. In certain preferred aspects, the crosslinkable compound of the organic underlayer coating composition and the crosslinkable compound of the overcoat coating composition each are polymers. In certain preferred aspects, the crosslinkable compound of the organic underlayer coating composition and the crosslinkable compound of the overcoat coating composition independently comprise a hydroxy-substituted aryl group or an amine group. In certain preferred aspects, the organic underlayer coating composition comprises a crosslinkable heterocyclic group. In certain preferred aspects, the crosslinkable heterocyclic group is an epoxide group, an oxetane group, or an aziridine group. In certain preferred aspects, the organic underlayer coating composition and the overcoat coating composition are free of free acids.

### BRIEF DESCRIPTION OF THE DRAWINGS

The present invention will be described with reference to the following drawings, in which like reference numerals denote like features, and in which:

FIGS. 1A-1H illustrate in cross-section an exemplary process flow for forming a semiconductor device in accordance with the invention; and

FIGS. 2A-2C illustrate in cross-section a comparative process flow of the Related Art.

### DETAILED DESCRIPTION OF THE INVENTION

The terminology used herein is for the purpose of describing particular embodiments only and is not intended to be limiting of the invention. The singular forms “a”, “an” and “the” are intended to include singular and plural forms, unless the context indicates otherwise. All ranges disclosed herein are inclusive of the endpoints, and the endpoints are independently combinable with each other. When an element is referred to as being “on” or “over” another element, it may be directly in contact with the other element or intervening elements may be present therebetween. In contrast, when an element is referred to as being “directly on” another element, there are no intervening elements present.

Unless otherwise indicated, a group that is “substituted” refers to a group having one or more of its hydrogen atoms replaced with one or more substituents. Exemplary substituent groups include, but are not limited to, isotopes of hydrogen such as deuterium, hydroxy (OH), halogen (e.g., F, Cl, I, Br), C₁₋₁₈ alkyl, C₁₋₈ haloalkyl, C₃₋₁₂ cycloalkyl, C₆₋₁₂ aryl having at least one aromatic ring (e.g., phenyl, biphenyl, naphthyl, or the like, each ring either substituted or unsubstituted aromatic), C₇₋₉ arylalkyl having at least one aromatic ring, C₇₋₁₂ alkylaryl, and combinations thereof. For purposes of carbon number determination, when a group is substituted, the number of carbon atoms of the group is the total number of carbon atoms in such group excluding those of any substituents.

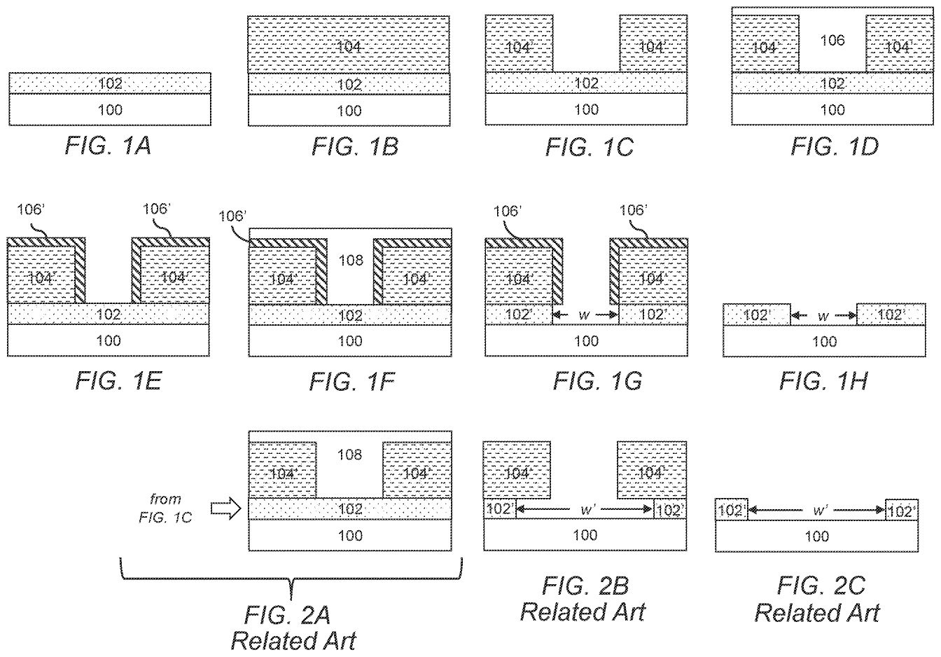

Methods of the invention in accordance with a first aspect will now be described with reference to FIGS. 1A-H. FIG. 1A depicts in cross-section a semiconductor substrate 100 comprising a metal layer 102 on the surface of the substrate. The semiconductor substrate can be of a material such as silicon or a compound semiconductor (e.g., III-V or II-VI), glass, quartz, sapphire, ceramic, copper, or the like. Typically, the substrate is a semiconductor wafer, such as single crystal silicon, and may have one or more layers and/or patterned features formed on a surface thereof. Layers forming part of the substrate may include, for example, one or more conductive layers such as layers of aluminum, copper, molybdenum, tantalum, titanium, tungsten, titanium tungsten, titanium nitride, titanium dioxide, titanium silicon nitride, tungsten nitride, tungsten carbonitride, nickel, copper, gold, other alloys, or nitrides or silicides of such metals, doped or undoped amorphous silicon or polysilicon, one or more dielectric layers such as layers of silicon oxide, silicon nitride, silicon oxynitride, or metal oxides, semiconductor layers such as single-crystal silicon, carbon layers and combinations thereof. The layers can be formed by various techniques, for example, chemical vapor deposition (CVD) such as plasma-enhanced CVD, low-pressure CVD, atomic layer deposition (ALD), or epitaxial growth, physical vapor deposition (PVD) such as sputtering or evaporation, electroplating, or a liquid coating technique such as spin-coating. The substrate may be any suitable size. Typical wafer substrate diameters are 200 to 300 mm, although wafers having smaller and larger diameters may be suitably employed according to the present invention.

The metal layer 102 is disposed over the surface of the substrate. The material for the metal layer 102 is not particularly limited, The metal layer 102 can be, for example, aluminum, copper, molybdenum, tantalum, titanium, tungsten, nickel, copper, gold, and alloys, nitrides, oxides, or silicides of such metals, such as titanium tungsten, titanium nitride, titanium dioxide, titanium silicon nitride, tungsten nitride, and tungsten carbonitride. Of these, tungsten, titanium nitride, titanium dioxide, titanium silicon nitride, and tungsten carbonitride are typical. The metal layer 102 can be formed by known methods, for example, ALD or other CVD techniques, sputtering, evaporation, or electroplating. Of these, ALD is preferred for use in creating very thin films such as those on the order of nanometers, tens of nanometers, or hundreds of nanometers. The thickness of the metal layer 102 is not particularly limited and can be, for example, 1 nm or greater, typically from 1 to 500 nm, from 1 to 300 nm, from 1 to 100 nm, or from 1 to 30 nm.

With reference to FIG. 1B, an organic underlayer 104 is formed on the metal layer 102. The organic underlayer is formed from an organic underlayer coating composition comprising a compound that is thermally crosslinkable and an organic solvent. Preferred underlayer coating compositions may be applied by various known coating techniques, for example, spin-coating, dip-coating, meniscus-coating, roller-coating, slot-coating, or spray-coating, with spin-coating being preferred. The organic underlayer coating compositions are substantially free of acid generators. “Substantially free of acid generators” as used herein means that the composition has a combined amount of thermal acid generator compounds and photoacid generator compounds in an amount of 2 wt % or less, typically 1 wt % or less, 0.5 wt % or less, or 0.1 wt % or less, based on total solids of the composition, or that the composition is completely free of such acid generator compounds. The underlayer coating compositions are thermally self-crosslinkable in the absence of acid generator compounds, meaning that one or more components of a layer formed from the underlayer coating composition are capable of crosslinking under thermal treatment in the absence of acid generator compounds.

The thermally crosslinkable compound includes crosslinkable groups chosen, for example, from hydroxyl-substituted aryl groups and amine groups, with phenol groups or amine groups being typical. The crosslinkable groups are present for both internal crosslinking of the underlayer and for interlayer crosslinking between the cured underlayer and overcoat layer to be coated over the underlayer. The thermally crosslinkable compound can be a polymer or can be in non-polymeric form, with a polymer being typical. Suitable polymers for the thermally crosslinkable compound include, for example, polyvinyl aromatics (e.g., polystyrenes), poly(meth)acrylates, polyvinylethers, polynorbornenes, polyesters, polyarylenes (e.g., polyphenols, novolacs), polyacetals, polyethylene glycols, polyamides, polyacrylamides, polyvinyl alcohols, and copolymers thereof. Typical are polymers formed by polymerization of an ethylenically unsaturated carbon-carbon double bond, preferably a polymerizable vinyl group, for example, a substituted or unsubstituted alkenyl group, a substituted or unsubstituted norbornyl group, a substituted or unsubstituted (meth)acrylic group, a substituted or unsubstituted vinyl ether group, a substituted or unsubstituted vinyl ketone group, a substituted or unsubstituted vinyl ester group, or a substituted or unsubstituted vinyl aromatic group. Of these, polyvinyl aromatics, poly(meth)acrylates, polyarylenes, and polyesters are typical. The polymer can be a homopolymer or can be a copolymer having a plurality of structurally distinct repeat units, for example, two, three, four, or more distinct repeat units. The copolymer may be a random copolymer, a block copolymer, or the like, with a random copolymer being typical. Typically, polymers of the underlayer compositions of the invention will have a weight average molecular weight (Mw) of from 1000 to about 60,000 Da, from 1000 to 50,000 Da, or from 2000 to 30,000 Da. Molecular weight of the polymers of the invention are suitably determined by gel permeation chromatography.

Suitable exemplary repeat units with a crosslinkable group for the thermally crosslinkable polymer include the following.

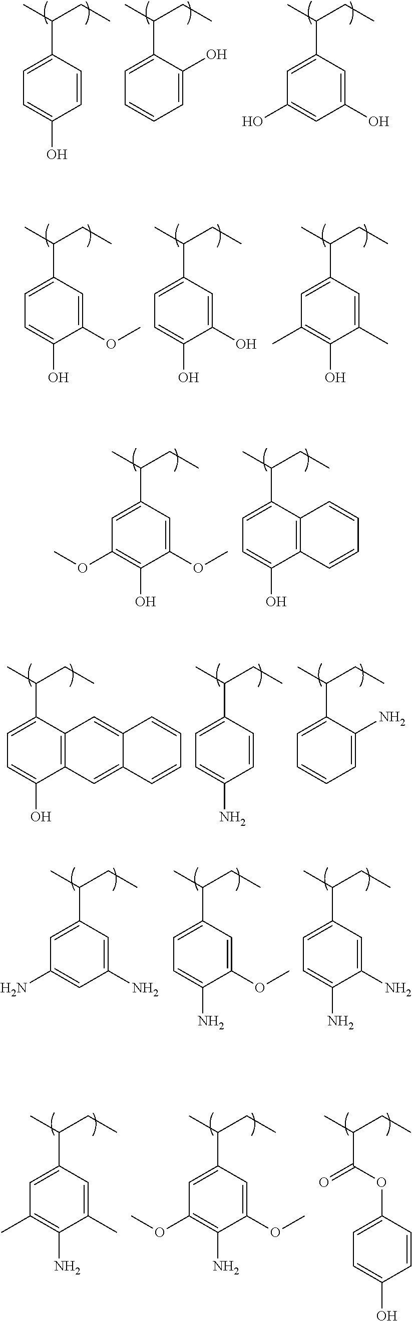

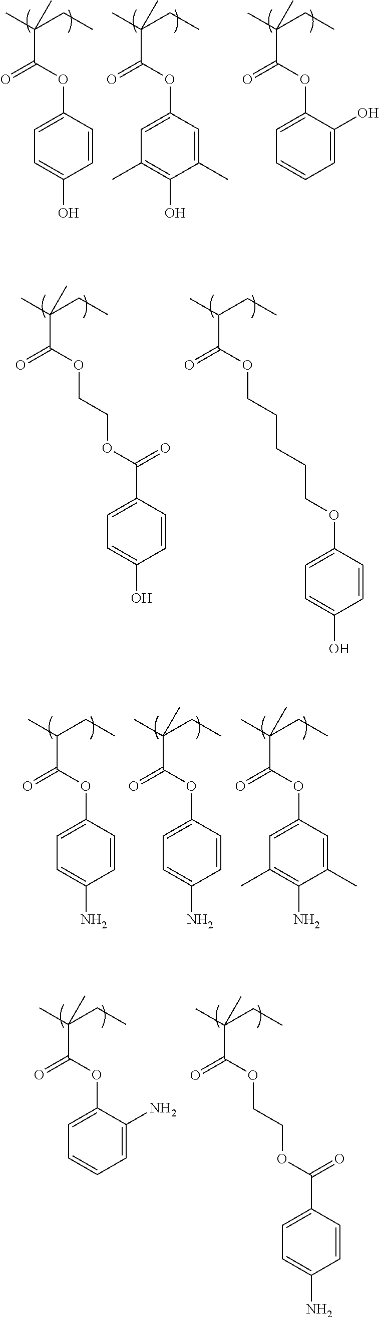

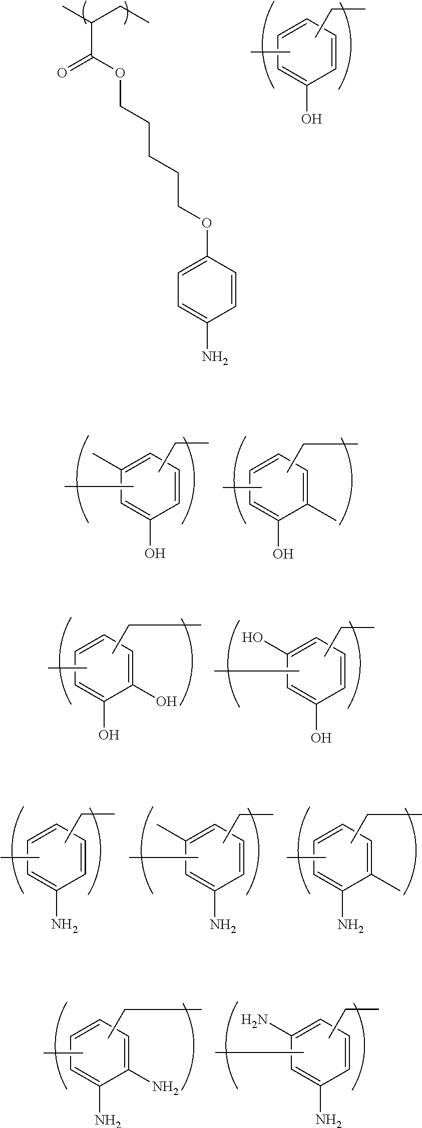

The polymer typically contains the repeat unit with a crosslinkable group in an amount from 5 to 100 mol %, more typically from 30 to 100 mol %, and still more typically from 40 to 100 mol %, based on the total repeating units in the polymer. In an embodiment, the polymer is a homopolymer. When the first polymer is a copolymer, the repeat unit is typically present in an amount from 1 to 99 mol %, more typically from 5 to 95 mol %, and still more typically from 10 to 90 mol %.

The thermally crosslinkable polymer may include one or more additional repeat units that are structurally different from the crosslinkable repeat unit. The one or more additional repeat unit can, for example, include one or more additional crosslinkable repeat units as described above that are structurally different from the first crosslinkable repeat unit, or may include other types of structurally different repeat units. The thermally crosslinkable polymer may, for example, include one or more additional repeat units of the types set forth above such as those present in polyvinyl aromatics (e.g., polystyrenes), poly(meth)acrylates, polyvinylethers, polynorbornenes, polyesters, polyarylenes (e.g., polyphenols, novolacs), polyacetals, polyethylene glycols, polyamides, poly(meth)acrylamides, polyvinyl alcohols, and combinations thereof. In the case of a copolymer, the one or more additional repeat units are typically present in the thermally crosslinkable polymer in an amount from 1 to 99 mol %, more typically from 5 to 95 mol %, and still more typically from 10 to 90 mol %, based on total repeat units in the polymer, with the sum of all repeat units of the polymer amounting to 100 mol %.

Suitable exemplary thermally crosslinkable polymers for use in the underlayer coating compositions include the following:

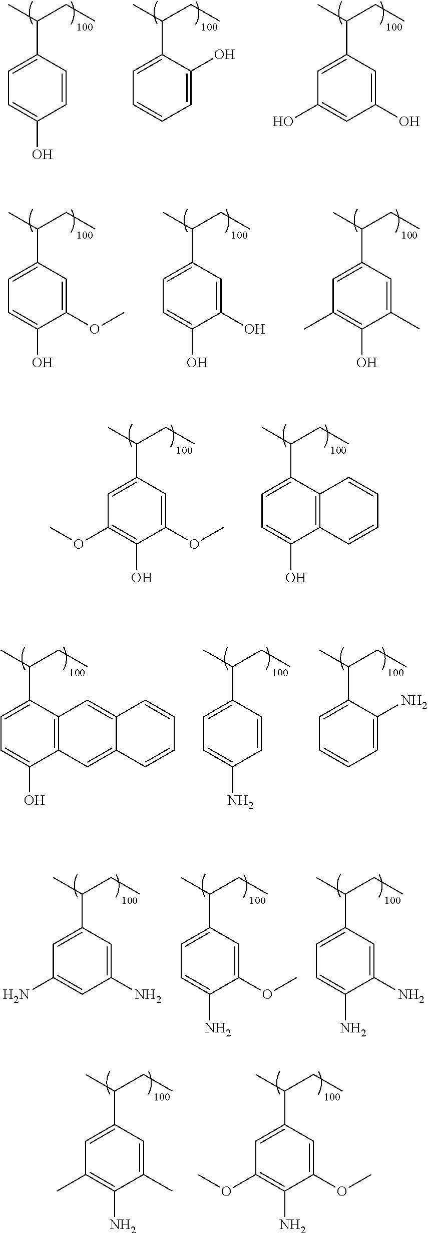

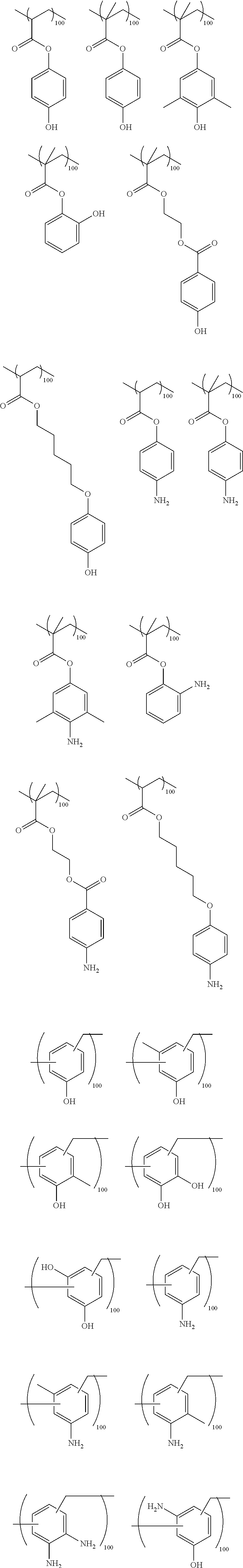

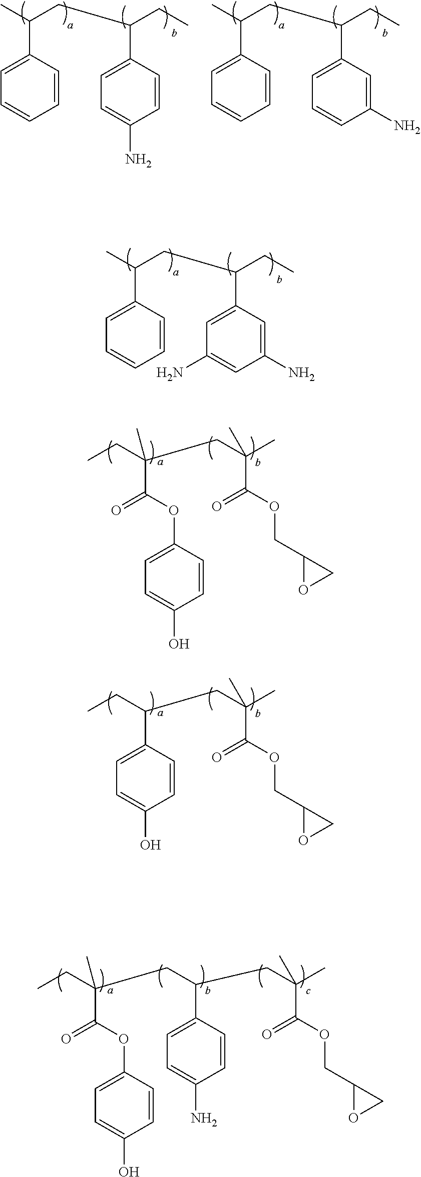

wherein a, b, and c represent mole % of the respective repeat unit within the polymer, with the total mole % of all units in the polymer being equal to 100 mole %.

Suitable non-polymeric (small molecule) thermally crosslinkable compounds include, for example, the monomeric precursors of the above-described crosslinkable polymers, or other non-polymeric compounds comprising one or more crosslinkable groups, for example, a hydroxyl-substituted aryl group or amine group.

The thermally crosslinkable compound is typically present in the underlayer coating composition in an amount of from 0.1 to 20 wt %, more typically from 1 to 10 wt %, based on total solids of the underlayer composition.

The organic underlayer coating composition preferably comprises a compound comprising one or more crosslinkable heterocyclic groups. The crosslinkable heterocyclic group is preferably chosen from an epoxide group, an oxetane group, an aziridine group, or a combination thereof. The compound comprising the one or more crosslinkable heterocyclic groups can be in polymeric or non-polymeric form, and can be the same compound as the thermally crosslinkable compound or a different compound. For example, in the case of a polymeric thermally crosslinkable compound, the polymer can include one or more repeat units comprising the crosslinkable heterocyclic group. In the case of a non-polymeric thermally crosslinkable compound as described above, the compound can further include a crosslinkable heterocyclic group. Alternatively, the crosslinkable heterocyclic group can be present in the underlayer coating composition as a distinct component from the thermally crosslinkable compound in polymeric or nonpolymeric form. As a distinct component from the thermally crosslinkable compound, the compound comprising the crosslinker component is typically present in the underlayer coating composition in an amount from 0.1 to 20 wt %, more typically from 1 to 10 wt %, based on total solids of the underlayer composition.

Suitable exemplary repeat units with a crosslinkable heterocyclic group include the following:

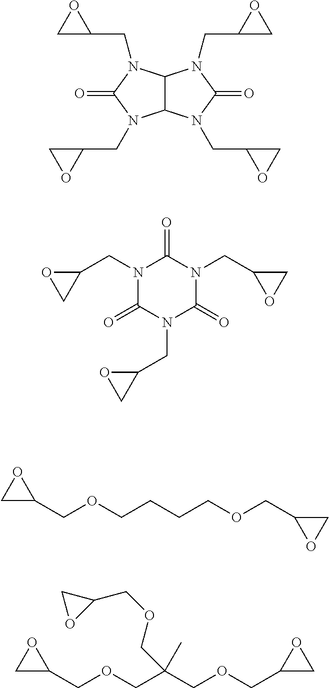

Suitable exemplary non-polymeric compounds comprising one or more crosslinkable heterocyclic groups include the following:

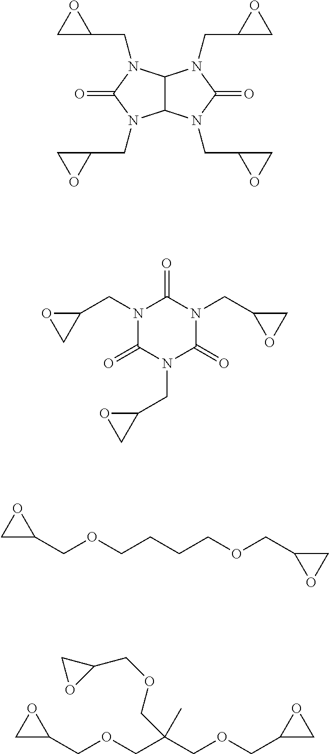 [SMILES: O=C1N(CC2CO2)C2C(N1CC1CO1)N(CC1CO1)C(=O)N2CC1CO1 ; O=c1n(CC2CO2)c(=O)n(CC2CO2)c(=O)n1CC1CO1 ; C(CCOCC1CO1)COCC1CO1 ; CC(COCC1CO1)(COCC1CO1)COCC1CO1]

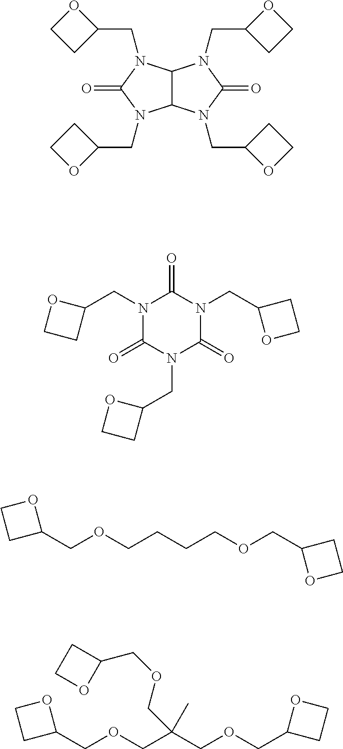 [SMILES: O=C1N(CC2CCO2)C2C(N1CC1CCO1)N(CC1CCO1)C(=O)N2CC1CCO1 ; O=c1n(CC2CCO2)c(=O)n(CC2CCO2)c(=O)n1CC1CCO1 ; C(CCOCC1CCO1)COCC1CCO1 ; CC(COCC1CCO1)(COCC1CCO1)COCC1CCO1]

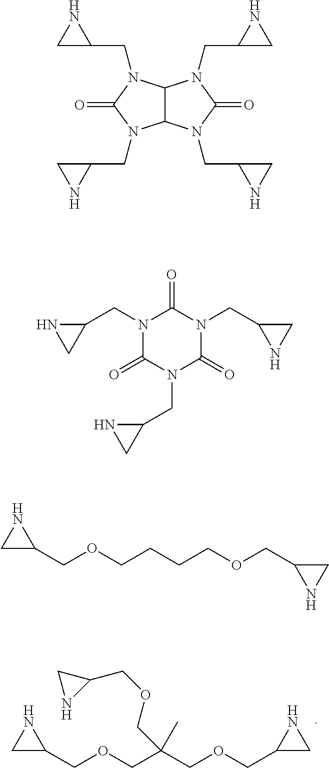 [SMILES: O=C1N(CC2CN2)C2C(N1CC1CN1)N(CC1CN1)C(=O)N2CC1CN1 ; O=c1n(CC2CN2)c(=O)n(CC2CN2)c(=O)n1CC1CN1 ; C(CCOCC1CN1)COCC1CN1 ; CC(COCC1CN1)(COCC1CN1)COCC1CN1]

The underlayer coating compositions may further include one or more additives chosen, for example, from crosslinking agents, surfactants, antioxidants, dyes, or other additives known to those skilled in the art. Any suitable crosslinking agent may be used in the underlayer coating compositions, provided that such crosslinking agent has at least 2, and preferably at least 3, moieties capable of reacting with another component of the composition, for example, the thermally crosslinkable compound, under suitable conditions. Exemplary crosslinking agents include, but are not limited to, novolac resins, epoxy-containing compounds, melamine compounds, guanamine compounds, isocyanate-containing compounds, benzocyclobutenes, benzoxazines, and the like, and typically any of the foregoing having 2 or more, more typically 3 or more substituents selected from methylol, C₁₋₁₀ alkoxymethyl, and C₂₋₁₀ acyloxymethyl. Examples of suitable crosslinking agents are those shown by formulae (1) and (2).

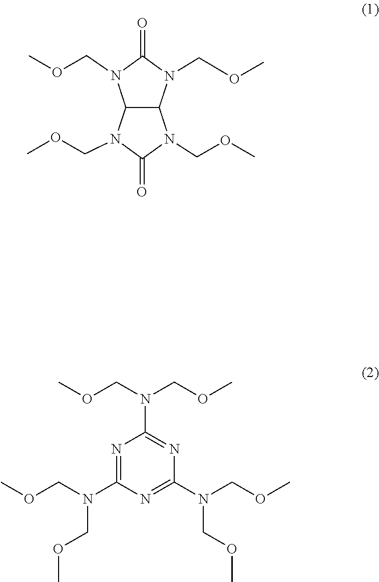

Such crosslinking agents are well-known in the art and are commercially available from a variety of sources. When present in the underlayer compositions, the amount of such crosslinking agents may be, for example, in the range of from greater than 0 to 50 wt %, and typically from greater than 0 to 30 wt %, based on total solids of the underlayer coating composition.

The present underlayer coating compositions may optionally include one or more surfactants (or surface leveling agents). Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (e.g., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Michigan USA) and PF-656 (Omnova Solutions, Beachwood, Ohio, USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in Mccutcheon's Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, PA and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.). Such surfactants if used may be present in the composition in minor amounts, for example from greater than 0 to 1 wt % based on total solids of the photoresist underlayer composition.

An antioxidant can be added to prevent or minimize oxidation of organic materials in the underlayer coating composition. Suitable antioxidants include, for example, phenol-based antioxidants, antioxidants composed of an organic acid derivative, sulfur-containing antioxidants, phosphorus-based antioxidants, amine-based antioxidants, antioxidant composed of an amine-aldehyde condensate and antioxidants composed of an amine-ketone condensate. Examples of the phenol-based antioxidant include substituted phenols such as 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butyl·hydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-α-dimethylamino-p-cresol, 6-(4-hydroxy-3,5-di-tert-butyl·anilino) 2,4-bis·octyl-thio-1,3,5-triazine, n-octadecyl-3-(4′-hydroxy-3′,5′-di-tert-butyl phenyl) propionate, octylated phenol, aralkyl-substituted phenols, alkylated p-cresol and hindered phenol; bis-, tris- and poly-phenols such as 4,4′-dihydroxy·diphenyl, methylene·bis(dimethyl-4,6-phenol), 2,2′-methylene-bis-(4-methyl-6-tert-butylphenol), 2,2′-methylene-bis-(4-methyl-6-cyclohexyl·phenol), 2,2′-methylene-bis-(4-ethyl-6-tert-butylphenol), 4,4′-methylene-bis-(2,6-di-tert-butylphenol), 2,2′-methylene-bis-(6-α-methyl-benzyl-p-cresol), methylene-crosslinked polyvalent alkylphenol, 4,4′-butylidenebis-(3-methyl-6-tert-butylphenol), 1,1-bis-(4-hydroxyphenyl)-cyclohexane, 2,2′-dihydroxy-3,3′-di-(α-methylcyclohexyl)-5,5′-dimethyl·diphenylmethane, alkylated bisphenol, hindered bisphenol, 1,3,5-trimethyl-2,4,6-tris(3,5-di-tert-butyl-4-hydroxybenzyl)benzene, tris-(2-methyl-4-hydroxy-5-tert-butylphenyl) butane, and tetrakis-[methylene-3-(3′,5′-di-tert-butyl-4′-hydroxyphenyl) propionate]methane. Suitable antioxidants are commercially available, for example, Irganox™ antioxidants (Ciba Specialty Chemicals Corp.). The antioxidants if used are typically present in the gap-fill composition in an amount of from 0.01 to 10 wt % based on total solids of the underlayer coating composition.

Underlayer coating compositions useful in the methods of the invention also may contain dye compounds that absorb radiation used to expose an overcoated photoresist layer. Such dye compounds, if used, may be present in an amount of 0.01 to 10 wt % based on total solids of the underlayer coating composition.

The underlayer coating compositions further include an organic solvent, which may be a single solvent or a mixture of solvents. Suitable solvents include, for example, one or more of oxyisobutyric acid esters, particularly methyl-2-hydroxyisobutyrate, 2-hydroxyisobutyric acid, ethyl lactate or one or more of the glycol ethers such as 2-methoxyethyl ether (Diglyme), ethylene glycol monomethyl ether, and propylene glycol monomethyl ether; solvents that have both ether and hydroxy moieties such as methoxy butanol, ethoxy butanol, methoxy propanol, and ethoxy propanol; methyl 2-hydroxyisobutyrate; esters such as methyl cellosolve acetate, ethyl cellosolve acetate, propylene glycol monomethyl ether acetate, dipropylene glycol monomethyl ether acetate and other solvents such as dibasic esters, propylene carbonate and gamma-butyro lactone; or a combination thereof.

The concentration of the dry components in the underlayer coating compositions will depend on several factors such as the method of application and target film thickness. Typically, the total solids content of the underlayer coating composition may be from 0.05 to 20 wt % of the total weight of the underlayer coating composition, preferably from 0.1 to 5 wt % of the underlayer coating composition.

The underlayer coating composition is applied on the substrate with a typical dried layer thickness of between about 0.02 and 0.5 μm, preferably a dried layer thickness of between about 0.04 and 0.20 μm. The applied underlayer is then cured before applying a photoresist composition over the underlayer. Cure conditions will vary with the components of the underlayer coating composition. Typical cure conditions are from 80° C. to 325° C., preferably from 150° C. to 300° C., for about 0.5 to 5 minutes. Cure conditions preferably render the underlayer substantially insoluble to the solvent of the photoresist composition to be coated on the underlayer.

After such curing, a photoresist composition is applied above the surface of the underlayer. A wide variety of photoresists may be suitably used in the methods of the invention and may be positive-tone materials or negative-tone materials. Suitable photoresists include, for example, materials within the EPIC series of photoresists available from DuPont Electronics & Industrial (Marlborough, Massachusetts). The photoresist composition can be applied to the substrate by known coating techniques such as described above with reference to the photoresist underlayer composition, with spin-coating being typical. The photoresist layer thickness can vary widely, with a typical thickness for the photoresist layer being from 10 to 300 nm. The photoresist layer is typically next softbaked to minimize the solvent content in the layer, thereby forming a tack-free coating and improving adhesion of the layer to the substrate. Preferably, essentially no intermixing of the underlayer and overcoated photoresist layer should occur. The softbake can be conducted on a hotplate or in an oven, with a hotplate being typical. Typical softbakes are conducted at a temperature of from 70 to 150° C., and a time of from 30 to 90 seconds.

The photoresist layer is next exposed to activating radiation through a photomask or by direct writing to create a difference in solubility between exposed and unexposed regions. References herein to exposing a photoresist composition to radiation that is activating for the composition indicates that the radiation can form a latent image in the photoresist composition. The photomask has optically transparent and optically opaque regions corresponding to regions of the resist layer to be exposed and unexposed, respectively, by the activating radiation. The exposure wavelength is typically sub-400 nm, and more typically, sub-300 nm, such as 248 nm (KrF), 193 nm (ArF), or an EUV wavelength (e.g., 13.5 nm). The activating radiation can be electron beam (e-beam), typically by direct writing to the photoresist layer. In a preferred aspect, the exposure wavelength is 248 nm, 193 nm, or an EUV wavelength. The exposure energy is typically from 3 to 300 mJ/cm², depending, for example, on the exposure tool and the components of the photosensitive composition.

Following exposure of the photoresist layer, a post-exposure bake (PEB) is typically performed. The PEB can be conducted, for example, on a hotplate or in an oven. The PEB is typically conducted at a temperature of 50° C. or greater, more typically a temperature in the range of from 50° C. to 160° C. The exposed photoresist layer is then developed with a suitable developer to selectively remove those regions of the layer that are soluble in the developer while the remaining insoluble regions form the resulting photoresist pattern relief image. In the case of a positive-tone photoresist, the exposed regions of the photoresist layer are removed during development and unexposed regions remain. Conversely, for a negative-tone photoresist, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers will depend on the materials of the photoresist composition, and may include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like. Suitable organic solvent developers include, for example, those chosen from ketones, esters, ethers, hydrocarbons, alcohols and mixtures thereof.

The developed substrate may then be selectively processed on those regions of the underlayer 104 bared of photoresist, for example, by dry-etching in accordance with procedures well known in the art. Suitable etching processes include, for example, a plasma etch such as an O₂, CF₄, or H₂/N₂ plasma etch, or a combination thereof. As shown in FIG. 1C, the result is a patterned underlayer 104′, thereby exposing regions of the underlying metal layer 102 in the regions that are not covered by the patterned organic underlayer. The photoresist pattern remaining after the etch can then be stripped from the substrate by a known photoresist stripping process, for example, by an O₂ plasma ash process.

With reference to FIG. 1D, an overcoat coating composition is next coated on the substrate over the patterned organic underlayer 104′ and exposed regions of the metal layer 102 to form an overcoat layer 106. The overcoat coating composition comprises a compound comprising a group that is capable of covalent bonding (crosslinking with) the organic underlayer, and an organic solvent. The overcoat composition is substantially free of acid generators. While an overcoat layer formed from the composition is capable of covalent bonding with the underlayer, the overcoat layer is not self-crosslinkable. This allows for a portion of an overlayer formed from the composition that is in contact with the underlayer to become crosslinked with the underlayer while other portions of the overcoat remain uncrosslinked. Suitable such compounds include those described above with respect to the underlayer coating composition for the thermally crosslinkable polymer and the compound comprising one or more crosslinkable heterocyclic groups. To allow for covalent bonding with the underlayer while avoiding self-crosslinking of the coated overcoat composition, the overcoat coating composition preferably includes (i) a compound comprising crosslinkable groups chosen, for example, from hydroxyl-substituted aryl groups or amine groups, or (ii) a compound comprising crosslinkable heterocyclic groups chosen from epoxide groups, oxetane groups, aziridine group, or a combination thereof, but not groups from both (i) and (ii). As described above with respect to the underlayer coating composition, the crosslinkable compound can be a polymer or can be in non-polymeric form, with a polymer being typical.

The crosslinkable compound of the overcoat coating composition preferably includes one or more groups to increase the hydrophobicity of the compound. Suitable such groups include, for example, (i) aromatic groups substituted with one or more halogen atoms (—F, —Br, —Cl, or —I), typically-F, or (ii) a substituted or unsubstituted alkyl group, for example a substituted or unsubstituted C₁₋₁₀ linear, C₃₋₁₀ branched, or C₃₋₁₀ cyclic alkyl group, preferable substituents of which are halogen atoms, typically-F. Preferable for such hydrophobic groups as part of a crosslinkable polymer are repeat units of one or both of the following general formulas (3) and (4):

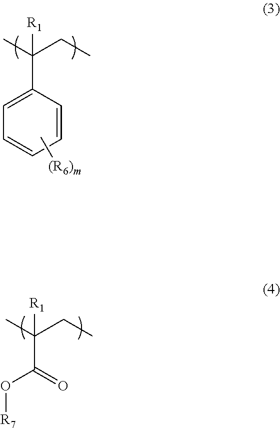

wherein: R₁ represents H, F, CN, substituted or unsubstituted C₁₋₁₀ alkyl, typically C₁₋₃ alkyl; R₆ independently represents F, OH, substituted or unsubstituted linear or branched C₁₋₂₀ alkyl, substituted or unsubstituted linear or branched C₁₋₂₀ alkoxy, and preferably wherein at least one R₆ is F or is at least partially fluorinated; and R₇ represents substituted or unsubstituted linear or branched C₁₋₂₀ alkyl, preferably fluoroalkyl; m is an integer from 0 to 5, typically from 1 to 5. Inclusion of such a repeat unit on the polymer is believed to enhance wet etch resistance of the overcoat layer to typical aqueous wet etchants that may be used to etch the metal layer 102. Suitable exemplary repeat units of formulas (3) and (4) include the following:

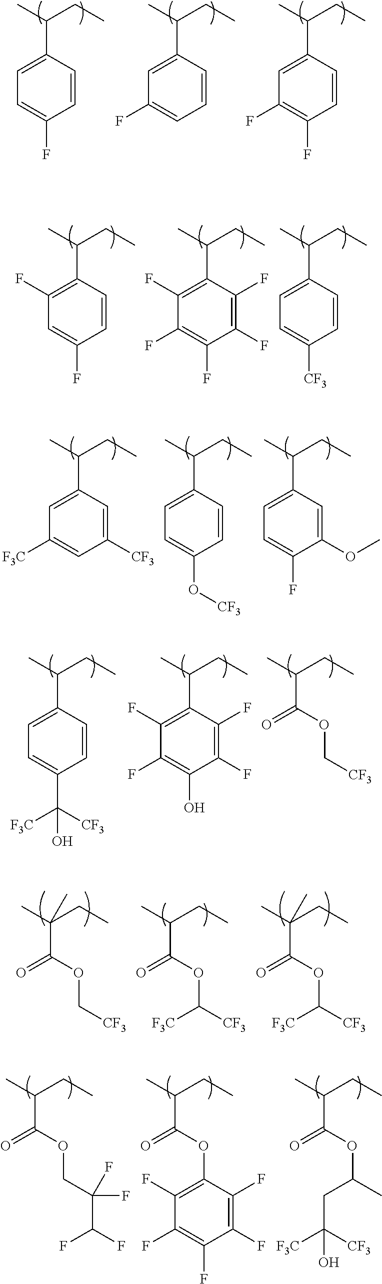

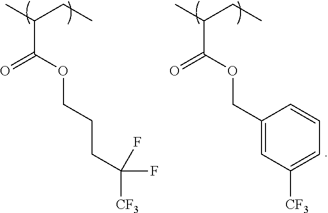

The optional repeat units of formulas (3) and (4) may be present in the crosslinkable polymer in an amount from 1 to 80 mol %, more typically from 10 to 60 mol %, based on total repeat units in the crosslinkable polymer, with the sum of all repeat units of the polymer amounting to 100 mol %.

In the case of a copolymer, the crosslinkable compound may be a random copolymer, a block copolymer, or the like, with a random copolymer being typical. Typically, polymers of the underlayer compositions of the invention will have a weight average molecular weight (Mw) of from 1000 to about 60,000 Da, from 1000 to 50,000 Da, or from 2000 to 30,000 Da. Molecular weight of the polymers of the invention are suitably determined by gel permeation chromatography.

Suitable exemplary crosslinkable polymers for use in the overcoat coating compositions include the following:

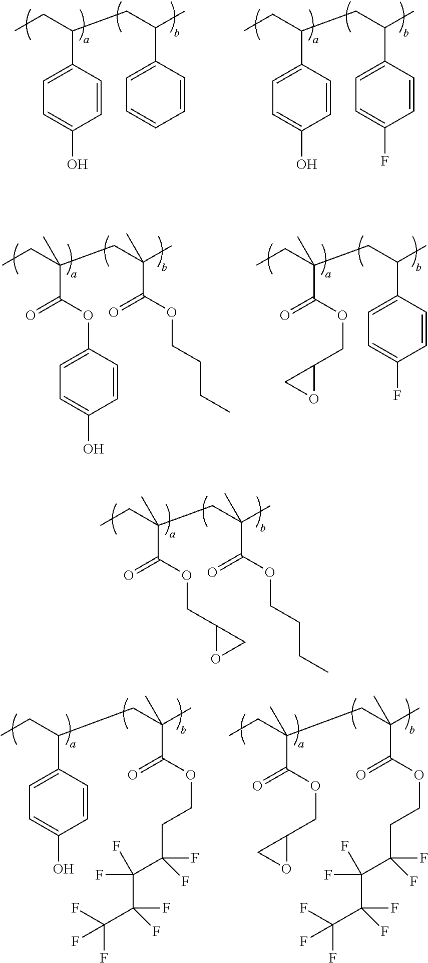

wherein a and b represent mole % of the respective repeat unit within the polymer, with the total mole % of all units in the polymer being equal to 100 mole %.

The crosslinkable compound is typically present in the overcoat coating composition in an amount of from 1 to 100 wt %, more typically from 1 to 99 wt % or from 10 to 90 wt %, based on total solids of the overcoat composition.

The overcoat coating compositions may further include one or more additives chosen, for example, from surfactants, antioxidants, dyes, or other additives known to those skilled in the art. Suitable such additives and typical amounts are described above with respect to the underlayer coating compositions. The overcoat coating compositions should be substantially free of crosslinking agents to avoid self-crosslinking of the overcoat layer.

The overcoat coating compositions further include an organic solvent, which may be a single solvent or a mixture of solvents. Suitable solvents include, for example, one or more of oxyisobutyric acid esters, particularly methyl-2-hydroxyisobutyrate, 2-hydroxyisobutyric acid, ethyl lactate or one or more of the glycol ethers such as 2-methoxyethyl ether (Diglyme), ethylene glycol monomethyl ether, and propylene glycol monomethyl ether; solvents that have both ether and hydroxy moieties such as methoxy butanol, ethoxy butanol, methoxy propanol, and ethoxy propanol; methyl 2-hydroxyisobutyrate; esters such as methyl cellosolve acetate, ethyl cellosolve acetate, propylene glycol monomethyl ether acetate, dipropylene glycol monomethyl ether acetate and other solvents such as dibasic esters, propylene carbonate and gamma-butyro lactone; or a combination thereof. The solvent of the overcoat coating composition should be selected such that the underlayer is substantially insoluble to the overcoat solvent.

The concentration of the dry components in the overcoat coating compositions will depend on several factors such as the method of application and target film thickness. Typically, the total solids content of the overcoat coating composition may be from 0.05 to 20 wt % of the total weight of the overcoat coating composition, preferably from 0.1 to 5 wt % of the overcoat coating composition.

The overcoat coating composition is applied on the substrate with a typical dried layer thickness of between about 0.02 and 0.5 μm, preferably a dried layer thickness of between about 0.04 and 0.20 μm. The applied overcoat layer is then cured, resulting in covalent bonding between the crosslinkable group of the overcoat composition and the organic underlayer. Cure conditions will vary with the components of the underlayer composition. Typical cure conditions are from 80° C. to 325° C., preferably from 150° C. to 300° C., for about 0.5 to 5 minutes.

With reference to FIG. 1E, a portion of the overcoat layer that is not crosslinked with the underlayer is removed from the substrate with an organic-based remover, leaving behind that portion of the overcoat layer 106′ that is crosslinked with the underlayer. Suitable removers for those portions of the overcoat material not bound to the underlayer include, for example, propylene glycol monomethyl ether, propylene glycol monomethyl ether acetate, methyl 2-hydroxyisobutyrate, ethyl lactate, and combinations thereof, with mixtures of PGME and PGMEA being preferred.

With reference to FIG. 1F, the substrate is next contacted with a wet etchant 108 to remove exposed regions of the metal layer 102, using the patterned photoresist underlayer and attached overcoat as an etching mask. Suitable wet etchants and conditions are known in the art and will depend, for example, on the particular material of the metal layer, underlayer and overcoat layer. The wet etchant can be, for example, an aqueous acidic or aqueous base solution, with SC-1 (e.g., 5:1:1 H₂O:H₂O₂:NH₄OH) and SC-2 (H₂O:H₂O₂:HCl (5:1:1) being typical.

As shown in FIG. 1G, the resulting etched region w of the metal layer exhibits some undercutting of the etching mask due to the isotropic nature of the wet etch. The presence of the overcoat is believed to provide improved wet-etch resistance and thus a reduced amount of undercutting as compared with a process in which the overcoat layer 106 is not employed. FIGS. 2A-C illustrate a process of the related art including an underlayer without use of an overcoat as described herein. As shown in FIGS. 2B-C, the wet-etched region w ‘in this overcoat free process would exhibit a significantly greater degree of undercutting of the etching mask 104’ than when using an underlayer with overcoat as described herein. This more extensive undercutting can adversely impact the resulting device structure and electrical characteristics of the final device. Those portions of the patterned overcoat layer 106′ and underlayer 102′ remaining after wet-etching of the metal layer can be removed from the substrate using known techniques and materials, for example, by oxygen plasma ashing, as shown in FIG. 1H.

Following the described patterning, further processing is conducted to form the final semiconductor device. The further processing can include, for example, to fabricate semiconductor devices such as memory devices, processor chips (CPUs), graphics chips, optoelectronic chips, LEDs, OLEDs, as well as other electronic devices.

The following non-limiting examples are illustrative of the invention.

### EXAMPLES

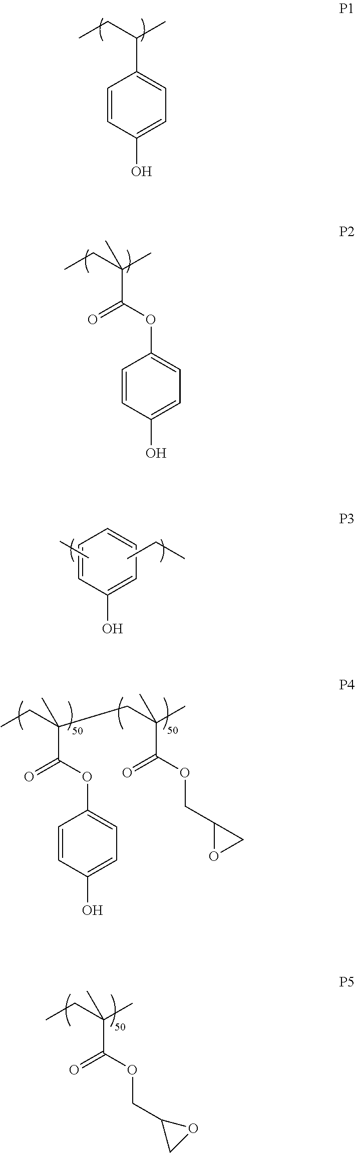

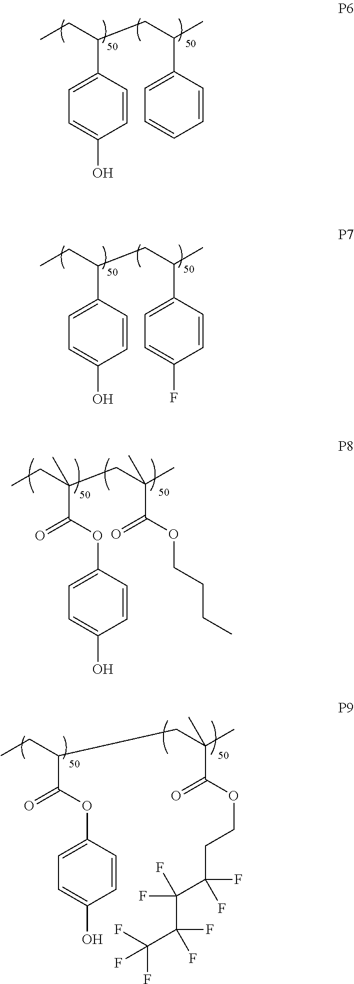

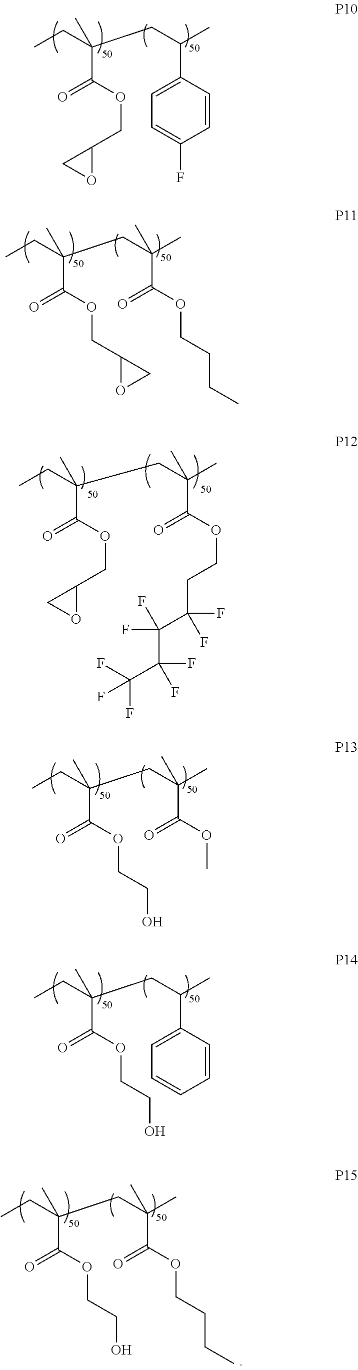

### Polymer Synthesis

Polymer P1 (Mw ~11,000) (Aldrich Chemical Co.).

### Example 1 (Polymer P2)

60.0 g ethyl lactate was charged into a 3-neck 250 ml round bottom flask equipped with a temperature controller unit. The reactor was heated to 90° C. and refluxed under nitrogen. 40.0 g 4-hydroxyphenyl methacrylate and 10.34 g V-601HP initiator (dimethyl 2,2′-azobis(2-methylpropionate)) (FUJIFILM Wako Chemicals) were dissolved in 60.0 g cyclohexanone, and the prepared mixture solution was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/Methyl tert-butyl ether (MTBE) (6:4) (×10 excess of reaction mixture). After the precipitate settled, the solvent was removed by decanting and the precipitate was dried in air. The resulting white solid precipitate was redissolved in 120 g tetrahydrofuran (THF) and precipitated from Heptane/MTBE (6:4). After the precipitate settled, the solvent was removed by decanting and the precipitate was then swapped with PGMEA solvent.

### Example 2 (Polymer P3)

To a 3-neck 100 mL round bottom flask equipped with a temperature control unit, 30.0 g o-cresol, 7.023 g paraformaldehyde, and 0.160 g methanesulfonic acid were dissolved in 30.0 g propylene glycol methyl ether (PGME). The reactor was heated to 120° C. for 5 hours. The reaction mixture was diluted to a 30 wt % solution with THF and precipitated with Heptane/MTBE (4:1) (×10 excess of reaction mixture). After the precipitate settled, the solvent was removed by decanting and the precipitate was dried at 40° C. in a vacuum oven for 1 day to form a dried powder. The dried polymer was swapped with PGMEA solvent.

### Example 3 (Polymer P4)

45.7 g propylene glycol monomethyl ether acetate (PGMEA) was charged into a 3-neck 250 ml round bottom flask equipped with a temperature controller unit. The reactor was heated to 90° C. 22.25 g 4-hydroxyphenyl methacrylate, 17.75 g glycidyl methacrylate, and 6.90 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/MTBE (6:4) (×10 excess of reaction mixture). After the precipitate settled, the solvent was removed by decanting and the precipitate was dried at 40° C. in a vacuum oven for 1 day to form a dried powder. The dried polymer was swapped with PGMEA solvent.

### Example 4 (Polymer P5)

24.1 g propylene glycol monomethyl ether acetate (PGMEA) was charged into a 3-neck 250 ml round bottom flask equipped with a temperature controller unit. The reactor was heated to 90° C. 40.0 g glycidyl methacrylate and 2.59 g V-601HP initiator (FUJIFILM Wako Chemicals) were dissolved in 74.3 g PGMEA, and the mixture was fed into the reactor for 180 minutes. After feeding was completed, the reactor was maintained at 90° C. for an additional 60 minutes. After reaction, the reactor was allowed to cool down to room temperature with stirring. The reaction mixture was diluted to a 25 wt % solution with THF and precipitated with MTBE (×10 excess of reaction mixture). After the precipitate settled, the solvent was removed by filtration and the precipitate was dried at 50° C. in a vacuum oven for 1 day.

### Example 5 (Polymer P6)

20.0 g PGMEA was charged into a 3-neck 250 ml round bottom flask equipped with a temperature controller unit. The reactor was heated to 75° C. 24.36 g 4-acetoxystyrene (ACS), 15.64 g styrene (Sty), and 3.36 g V-65 initiator (2,2′-azobis(2,4-dimethylvaleronitrile)) (FUJIFILM Wako Chemicals) were dissolved in 40.0 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Methanol (MeOH) (×10 excess of reaction mixture). After the precipitate settled, the solvent was removed by filtration and the precipitate was dried at 40° C. in a vacuum oven for 1 day to form a dried powder. 20.0 g of the dried powder and 0.487 g of 25 wt % Sodium methoxide (NaOMe) in MeOH were dissolved in 46.67 g MeOH in a round bottom flask equipped with a condenser and a magnetic stir bar. The solution was then heated to 65° C. with stirring for 5 hours. The solvent was evaporated on a rotatory evaporator and the resulting product was dissolved in ethyl acetate and washed with deionized water. The organic layer was separated and the solvent was removed on a rotatory evaporator. The polymer was swapped with PGMEA solvent.

### Example 6 (Polymer P7)

20.0 g propylene glycol monomethyl ether acetate (PGMEA) was charged into a 3-neck 250 ml round bottom flask equipped with a temperature controller unit. The reactor was heated to 75° C. 22.82 g 4-acetoxystyrene (ACS), 17.18 g 4-fluorostyrene (FS), and 3.15 g V-65 initiator (FUJIFILM Wako Chemicals) were dissolved in 40.0 g PGMEA. The mixture was fed into the reactor for 180 minutes. After feeding was completed, the reactor was maintained at 90° C. for additional 60 minutes. After reaction, the reactor was allowed to cool down to room temperature with stirring naturally. The reaction mixture was precipitated with MeOH (×10 excess of reaction mixture). After the precipitate settled, the solvent was removed by filtration and the precipitate was dried at 40° C. in a vacuum oven for 1 day to form a dried powder. 20.0 g of the dried powder and 0.456 g of 25% NaOMe in MeOH were dissolved in 46.67 g MeOH in a round bottom flask equipped with a condenser and a magnetic stir bar. The solution was then heated to 65° C. with stirring for 5 hours. The solvent was evaporated on a rotatory evaporator and the resulting product was dissolved in ethyl acetate and washed with deionized water. The organic layer was separated and the solvent was removed on a rotatory evaporator. The polymer was swapped with PGMEA solvent.

### Example 7 (Polymer P8)

45.7 g propylene glycol monomethyl ether acetate (PGMEA) was charged into a 3-neck 250 ml round bottom flask equipped with a temperature controller unit. The reactor was heated to 90° C. 22.25 g 4-hydroxyphenyl methacrylate, 17.75 g n-butyl methacrylate, and 6.90 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/MTBE (1:1) (×10 excess of reaction mixture). After the precipitate settled, the solvent was removed by decanting and the precipitate was dried at 40° C. in a vacuum oven for 1 day. The polymer was swapped with PGMEA solvent.

### Example 8 (Polymer P9)

20.0 g PGMEA was charged into a 3-neck 250 ml round bottom flask equipped with a temperature controller unit. The reactor was heated to 75° C. 13.12 g 4-acetoxystyrene, 26.88 g 3,3,4,4,5,5,6,6,6-nonafluorohexyl methacrylate, and 1.81 g V-65 initiator (FUJIFILM Wako Chemicals) were dissolved in 40.0 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with MeOH (×10 excess of reaction mixture). After the precipitate settled, the solvent was removed by filtration and the precipitate was dried at 40° C. in a vacuum oven for 1 day to form a dried powder. 20.0 g of the dried powder and 0.262 g 25% NaOMe in MeOH were dissolved in 46.67 g MeOH in a round bottom flask with a condenser and a magnetic stir bar. The solution was heated to 65° C. with stirring for 5 hours. After the solvent was evaporated on a rotatory evaporator, the resulting product was dissolved in ethyl acetate and washed with deionized water. The organic layer was separated, and solvent was removed with a rotatory evaporator. The polymer was swapped with PGMEA solvent.

### Example 9 (Polymer P10)

45.7 g PGMEA was charged into a 3-neck 250 ml round bottom flask equipped with a temperature controller unit. The reactor was heated to 90° C. 21.51 g glycidyl methacrylate, 18.49 g 4-fluorostyrene, and 8.36 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with isopropanol (IPA) (× excess of reaction mixture). After the precipitate settled, the solvent was removed by filtration and the precipitate was dried at 40° C. in a vacuum oven for 1 day.

### Example 10 (Polymer P11)

45.7 g PGMEA was charged into a 3-neck 250 ml round bottom flask equipped with a temperature controller unit. The reactor was heated to 90° C. 20.0 g glycidyl methacrylate, 20.0 g n-butyl methacrylate, and 7.77 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with IPA (×10 excess of reaction mixture). After the precipitate settled, the solvent was removed by filtration and the precipitate was dried at 40° C. in a vacuum oven for 1 day.

### Example 11 (Polymer P12)

45.7 g PGMEA was charged into a 3-neck 250 ml round bottom flask equipped with a temperature controller unit. The reactor was heated to 90° C. 11.99 g glycidyl methacrylate, 28.01 g 3,3,4,4,5,5,6,6,6-nonafluorohexyl methacrylate, and 4.66 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with heptane (×10 excess of reaction mixture). After the precipitate settled, the solvent was removed by filtration and the precipitate was dried at 40° C. in a vacuum oven for 1 day.

### Example 12 (Polymer P13)

45.7 g PGMEA was charged into a 3-neck 250 ml round bottom flask equipped with a temperature controller unit. The reactor was heated to 90° C. 22.60 g 2-hydroxyethyl methacrylate, 17.40 g methyl methacrylate, and 9.60 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/MTBE (4:1) (×10 excess of reaction mixture). After the precipitate settled, the solvent was removed by decanting. The precipitate was then dried at 40° C. in a vacuum oven for 1 day.

### Example 13 (Polymer P14)

45.7 g PGMEA was charged into a 3-neck 250 ml round bottom flask equipped with a temperature controller unit. The reactor was heated to 90° C. 22.22 g 2-hydroxyethyl methacrylate, 17.78 g styrene, and 9.44 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/MTBE (4:1) (×10 excess of reaction mixture). After the precipitate settled, the solvent was removed by decanting. The precipitate was then dried at 40° C. in a vacuum oven for 1 day.

### Example 14 (Polymer P15)

45.7 g PGMEA was charged into a 3-neck 250 ml round bottom flask equipped with a temperature controller unit. The reactor was heated to 90° C. 19.11 g 2-hydroxyethyl methacrylate, 20.89 g n-butyl methacrylate, and 8.12 g V-601HP initiator (FUJIFILM Wako Chemicals) were dissolved in 74.3 g PGMEA. The mixture was fed into the reactor for 180 minutes. After feeding was completed, the reactor was maintained at 90° C. for an additional 60 minutes. After reaction, the reactor was allowed to cool down to room temperature with stirring. The reaction mixture was precipitated with Heptane/MTBE (4:1) (×10 excess of reaction mixture). After the precipitate settled, the solvent was removed by decanting. The precipitate was then dried at 40° C. in a vacuum oven for 1 day.

### Preparation of Underlayer Compositions

### Examples 15-20

Underlayer compositions (UC) were prepared by dissolving solid components in solvents using the materials and amounts set forth in Table 1. The mixture was shaken on a mechanical shaker for at least 4 hours. The resulting mixtures were filtered through a PTFE 0.45 μm membrane filter.

TABLE 1

| | Under- | | | | | |
|---|---|---|---|---|---|---|
| | layer | | | | | |
| Exam- | Compo- | Poly- | Cross- | Acid | Addi- | |
| ple | sition | mer | linker | Catalyst | tive | Solvent |
| Ex. 15 | UC-1 | P1 (3) | — | — | — | S1 (65.8) |
| | | P5 (3) | | | | S2 (28.2) |
| Ex. 16 | UC-2 | P2 (3) | — | — | — | S1 (65.8) |
| | | P5 (3) | | | | S2 (28.2) |
| Ex. 17 | UC-3 | P3 (3) | — | — | — | S1 (65.8) |
| | | P5 (3) | | | | S2 (28.2) |
| Ex. 18 | UC-4 | P4 (6) | — | — | — | S1 (65.8) |
| | | | | | | S2 (28.2) |
| Ex. 19 | UC-5 | P1 (2.7) | — | — | A1 | S1 (65.8) |
| | | P5 (2.7) | | | (0.6) | S2 (27.9) |
| Ex. 20 | UC-6 | P1 | C1 | T1 | — | S1 (65.8) |
| (Comp) | | (5.01) | (0.9) | (0.09) | | S2 (27.9) |

S1 = Methyl-2-hydroxy isobutyrate (HBM);
S2 = PGMEA; all amounts provided are in grams; polymer content reflects solids only, with any solvent portion of polymer reflected in solvent content.

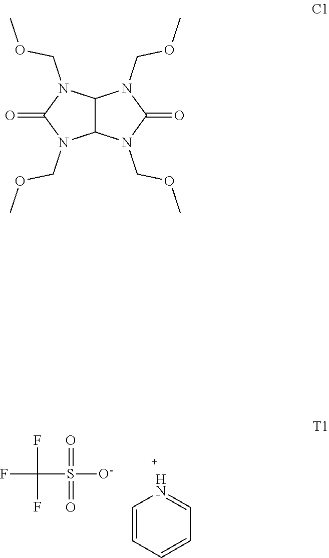

### Preparation of Overcoat Compositions

### Examples 21-30

Overcoat compositions (OC) were prepared by dissolving solid components in solvents using the materials and amounts set forth in Table 2. The mixture was shaken on a mechanical shaker for at least 4 hours. The resulting mixtures were filtered through a PTFE 0.45 μm membrane filter.

TABLE 2

| | Overcoat | | |
|---|---|---|---|
| Example | Composition | Polymer | Solvent |
| Ex. 21 | OC-1 | P6 (6) | S2 (93) |
| Ex. 22 | OC-2 | P7 (6) | S2 (93) |
| Ex. 23 | OC-3 | P8 (6) | S2 (93) |
| Ex. 24 | OC-4 | P9 (6) | S2 (93) |
| Ex. 25 | OC-5 | P10 (6) | S2 (93) |
| Ex. 26 | OC-6 | P11 (6) | S2 (93) |
| Ex. 27 | OC-7 | P12 (6) | S2 (93) |
| Ex. 28 (Comp) | OC-8 | P13 (6) | S2 (93) |
| Ex. 29 (Comp) | OC-9 | P14 (6) | S2 (93) |
| Ex. 30 (Comp) | OC-10 | P15 (6) | S2 (93) |

S2 = PGMEA; all amounts provided are in grams; polymer content reflects solids only, with any solvent portion of polymer reflected in solvent content.

### Solvent Strip-Resistance/Strippability Evaluation

### Examples 31-46

Underlayer compositions or overcoat compositions as described above were spin-coated onto a respective 200-mm silicon wafer on an ACT-8 Clean Track (Tokyo Electron Co.) at 1500 rpm for 60 seconds, and then baked at 220° C. for 60 seconds on a hot plate to form an underlayer or overcoat film. The film thickness was then measured with a Therma-Wave OptiProbe™ 5250 metrology tool. 30 mL of PGME/PGMEA (70/30 wt/wt) remover was then applied to the film for 90 seconds on the Clean Track. The wafers were spin-dried at 4000 rpm for 60 seconds and soft-baked on a hot plate at 110° C. for 60 seconds. The thickness of each film was again measured to determine the amount of film thickness lost. The change in film thickness before and after applying the remover (i.e., the thickness of the film removed by the remover) was calculated using the following Equation 1:

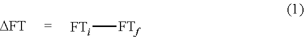

wherein FTᵢ is the underlayer or overcoat composition initial film thickness (prior to application of the remover), and FT_{f} is the final film thickness (after application of the remover). The results are shown in Table 3.

TABLE 3

| | | FTᵢ | FT_{f} | ΔFT |
|---|---|---|---|---|
| Example | Composition | (nm) | (nm) | (nm) |
| Ex. 31 | UC-1 | 150 | 149.5 | 0.5 |
| Ex. 32 | UC-2 | 150 | 149.6 | 0.4 |
| Ex. 33 | UC-3 | 150 | 149.4 | 0.6 |
| Ex. 34 | UC-4 | 150 | 149.7 | 0.3 |
| Ex. 35 | UC-5 | 150 | 149.5 | 0.5 |
| Ex. 36 (Comp) | UC-6 | 150 | 149.6 | 0.4 |
| Ex. 37 | OC-1 | 150 | 0.2 | 149.8 |
| Ex. 38 | OC-2 | 150 | 0.1 | 149.9 |
| Ex. 39 | OC-3 | 150 | 0.3 | 149.7 |
| Ex. 40 | OC-4 | 150 | 0.7 | 149.3 |
| Ex. 41 | OC-5 | 150 | 0.4 | 149.6 |
| Ex. 42 | OC-6 | 150 | 0.2 | 149.8 |
| Ex. 43 | OC-7 | 150 | 0.5 | 149.5 |
| Ex. 44 (Comp) | OC-8 | 150 | 0.8 | 149.2 |
| Ex. 45 (Comp) | OC-9 | 150 | 0.6 | 149.4 |
| Ex. 46 (Comp) | OC-10 | 150 | 0.9 | 149.1 |

As can be seen from Table 3, each of the underlayer compositions UC-1 to UC-6 exhibited negligible strip loss by the organic remover, indicating full crosslinking of the composition. The overcoat compositions OC-1 to OC-10 each showed substantially complete removal by the remover.

### Interlayer Crosslinking Evaluation

### Examples 47-61

Underlayer compositions as set forth in Table 4 were spin-coated onto a respective 200-mm silicon wafer on an ACT-8 Clean Track (Tokyo Electron Co.) at 1500 rpm for 60 seconds. The wafers were then baked at 220° C. for 60 seconds on a hot plate to form a 150 nm thick cured underlayer, as measured with a Therma-Wave OptiProbe™ 5250 metrology tool. An overcoat composition as set forth in Table 4 was spin-coated over the underlayer at 1500 rpm for 60 seconds. The wafer was baked at 220° C. for 60 seconds and then allowed to cool down to room temperature. 30 mL of PGME/PGMEA (70/30 wt/wt) remover was then applied to the film for 90 seconds on the Clean Track. The wafers were spin-dried at 4000 rpm for 60 seconds and soft-baked on a hot plate at 110° C. for 60 seconds. The thickness of the resulting bi-layer film was measured with the metrology tool. The attached overcoat thickness (FT_{oc}) was calculated as the difference between the final thickness of the bi-layer film (FT_{f}) and the initial thickness of underlayer film (FTᵢ) using the following Equation 2, with the results being shown in Table 4:

$$F {T}_{o c} = F {T}_{f} - F {T}_{i} \qquad ( 2 )$$

TABLE 4

| | Underlayer | Overcoat | FTᵢ | FT_{f} | FT_{oc} |
|---|---|---|---|---|---|
| Example | Composition | Composition | (nm) | (nm) | (nm) |
| Ex. 47 | UC-1 | OC-1 | 150 | 165 | 15 |
| Ex. 48 | UC-2 | OC-1 | 150 | 163 | 13 |
| Ex. 49 | UC-3 | OC-1 | 150 | 162 | 12 |
| Ex. 50 | UC-4 | OC-1 | 150 | 164 | 14 |
| Ex. 51 | UC-5 | OC-1 | 150 | 168 | 18 |
| Ex. 52 (Comp) | UC-6 | OC-1 | 150 | 150 | 0 |
| Ex. 53 | UC-1 | OC-2 | 150 | 162 | 12 |
| Ex. 54 | UC-1 | OC-3 | 150 | 169 | 19 |
| Ex. 55 | UC-1 | OC-4 | 150 | 167 | 17 |
| Ex. 56 | UC-1 | OC-5 | 150 | 157 | 7 |
| Ex. 57 | UC-1 | OC-6 | 150 | 159 | 9 |
| Ex. 58 | UC-1 | OC-7 | 150 | 160 | 10 |
| Ex. 59 (Comp) | UC-1 | OC-8 | 150 | 150 | 0 |
| Ex. 60 (Comp) | UC-1 | OC-9 | 150 | 150 | 0 |
| Ex. 61 (Comp) | UC-1 | OC-10 | 150 | 150 | 0 |

As can be seen from Table 4, bilayer stacks of Comparative Examples 52 and 59-61 exhibited thicknesses after solvent strip that were equal to the thickness of the underlayer, indicating no significant amount of the overcoat layer remained attached to the underlayer, believed to result from an absence of interlayer crosslinking between the underlayer and overcoat layer. In contrast, the bilayer stacks of Examples 47-51 and 53-58 in accordance with the invention exhibited thicknesses after solvent strip that were greater than the thickness of the underlayer. This is indicative of the occurrence of interlayer crosslinking between the underlayer and overcoat films.

### Wet-Etch Resistance Evaluation

### Examples 62-81

Titanium nitride (TiN) was deposited on a 200-mm silicon wafer by atomic layer deposition (ALD) using tetrakis(dimethylamino) titanium (TDMAT) as the precursor on a Nano-ALD2000 ALD system (Integrated Process Systems Ltd.) at 10 SCCM and 0.34 Torr total pressure, the deposition cycle being repeated to reach a target thickness of 10 nm. The deposited wafers were cut into coupons (4 cm×4 cm pieces) before spin-coating underlayer and overcoat compositions as set forth in Table 5, with coating, curing, film thickness measurement being conducted as described above with respect to the interlayer crosslinking evaluation, using a J. A. Woollam M-2000 ellipsometer for thickness measurement. The resulting multilayer film stacks were dipped into an SC-1 wet-etching solution for evaluation of wet-etch resistance. The etching solution was prepared by mixing 35 wt % ammonium hydroxide and 30 wt % hydrogen peroxide (NH₄OH:H₂O₂:H₂O=1:1:10) with a bath temperature of 50° C. The resistance of the films to the wet-etchant was evaluated by measuring the endurance time (tend) until damage to the film was visually observed. The results are shown in Table 5.

TABLE 5

| | | | Attached | Endurance |
|---|---|---|---|---|
| | Underlayer | Overcoat | Thickness | Time |
| Example | Comp. | Comp. | (nm) | (min) |
| Ex. 62 | UC-1 | — | 0 | 7 |
| (Comp) | | | | |
| Ex. 63 | UC-2 | — | 0 | 7 |
| (Comp) | | | | |
| Ex. 64 | UC-3 | — | 0 | 8 |
| (Comp) | | | | |
| Ex. 65 | UC-4 | — | 0 | 7 |
| (Comp) | | | | |
| Ex. 66 | UC-5 | — | 0 | 7 |
| (Comp) | | | | |
| Ex. 67 | UC-1 | OC-1 | 55 | 10 |
| Ex. 68 | UC-2 | OC-1 | 43 | 11 |
| Ex. 69 | UC-3 | OC-1 | 32 | 12 |
| Ex. 70 | UC-4 | OC-1 | 44 | 10 |
| Ex. 71 | UC-5 | OC-1 | 58 | 11 |
| Ex. 72 | UC-6 | OC-1 | 0 | 7 |
| (Comp) | | | | |
| Ex. 73 | UC-1 | OC-2 | 57 | 9 |
| Ex. 74 | UC-1 | OC-3 | 61 | 9 |
| Ex. 75 | UC-1 | OC-4 | 63 | 9 |
| Ex. 76 | UC-1 | OC-5 | 48 | 8 |
| Ex. 77 | UC-1 | OC-6 | 54 | 8 |
| Ex. 78 | UC-1 | OC-7 | 52 | 8 |
| Ex. 79 | UC-1 | OC-8 | 0 | 7 |
| (Comp) | | | | |
| Ex. 80 | UC-1 | OC-9 | 0 | 7 |
| (Comp) | | | | |
| Ex. 81 | UC-1 | OC-10 | 0 | 7 |
| (Comp) | | | | |

Based on the results in Table 5, use of an overcoat layer that is crosslinkable with the underlayer resulted in improved wet etch resistance of the underlayer film as compared with use of an underlayer alone (Comparative Examples 62-66), or an underlayer and overcoat combination that do not exhibit interlayer crosslinking (Comparative Examples 72 and 79-81).

1. A method of forming a semiconductor device, comprising:
(a) providing a semiconductor substrate comprising a metal layer;
(b) forming an organic underlayer on the metal layer from an organic underlayer coating composition comprising a crosslinkable compound and a solvent, wherein the organic underlayer is self-crosslinkable and is substantially free of acid generators;
(c) curing the organic underlayer, thereby crosslinking the organic underlayer;
(d) patterning the cured organic underlayer, thereby exposing regions of the metal layer that are not covered by the patterned organic underlayer;
(e) applying an overcoat coating composition on the substrate comprising the patterned organic underlayer, wherein the overcoat coating composition comprises a crosslinkable compound that is crosslinkable with the patterned organic underlayer; and an organic solvent; wherein the overcoat coating composition is substantially free of acid generators;
(f) curing the overcoat coating composition to cause crosslinking between the compound and the patterned organic underlayer, wherein the resulting overcoat comprises a first portion that is crosslinked with the organic underlayer and a second portion that is not crosslinked with the organic underlayer;
(g) removing the second portion of the overcoat from the substrate with an organic-based solution; and
(h) wet etching the metal layer using the patterned organic underlayer and the first portion of the overcoat as an etching mask.

2. The method of claim 1, further comprising (i) removing the patterned organic underlayer and the crosslinked portion of the overcoat composition from the substrate.

3. The method of claim 1, wherein the metal layer is chosen from tungsten, titanium nitride, titanium dioxide, titanium silicon nitride, or tungsten carbonitride.

4. The method of claim 1, wherein the crosslinkable compound of the organic underlayer coating composition and the crosslinkable compound of the overcoat coating composition each are polymers.

5. The method of claim 1, wherein the crosslinkable compound of the organic underlayer coating composition and the crosslinkable compound of the overcoat coating composition independently comprise a hydroxy-substituted aryl group or an amine group.

6. The method of claim 1, wherein the organic underlayer coating composition comprises a crosslinkable heterocyclic group.

7. The method of claim 6, wherein the crosslinkable heterocyclic group is an epoxide group, an oxetane group, or an aziridine group.

8. The method of claim 1, wherein the organic underlayer coating composition and the overcoat coating composition are free of free acids.
